(19) United States
(12) Patent Application Publication
(10) Pub. No.: US 2007/0154735 A1
(43) Pub. Date: Jul. 5, 2007

(54) Organic EL element and organic EL display

(75) Inventor: Masaya Nakayama, Kanagawa (JP)

Correspondence Address: BIRCH STEWART KOLASCH & BIRCH, PO BOX 747, FALLS CHURCH, VA, 22040-0747, US

(73) Assignee: FUJI PHOTO FILM CO., LTD., Minami-Ashigara-Shi (JP)

(21) Appl. No.: 11/386,675

(22) Filed: Mar. 23, 2006

(30) Foreign Application Priority Data
Mar. 23, 2005 (JP) 2005-084525

(51) Int. Cl. B32B 19/00

(52) U.S. Cl. 428/690

(57) ABSTRACT

The organic EL element of the invention includes an organic thin layer which includes at least a light-emitting layer, between a positive electrode and a negative electrode, wherein a layer in the organic thin layer includes a 1,3,6,8-tetraphenylpyrene compound expressed by the following structural formula (1) and a triphenylbenzene derivative expressed by the following structural formula (2). Preferably, the triphenylbenzene derivative is 1,3,5-tris[4-(N-carbazolyl)phenyl]benzene (TCPB).

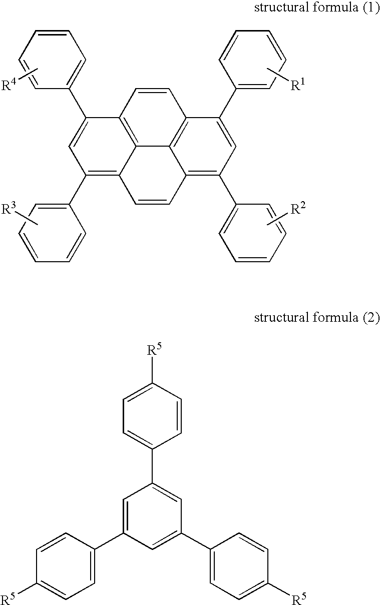

In the structural formula (1), R¹ to R⁴ represent one of a hydrogen atom, alkyl group, cycloalkyl group, and aryl group. In the structural formula (2), R⁵ represents a carbazole skeleton expressed by the following structural formula (3).

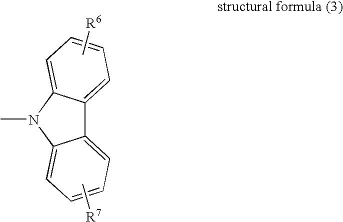

In the structural formula (3), R⁶ and R⁷ represent a hydrogen atom, or a substituent group.

### BACKGROUND OF THE INVENTION

1. Field of the Invention

The present invention organic EL elements having high luminous efficiency over a wide range of current densities covering driving currents, high luminance, and satisfactory color purity, and high-performance organic EL display in which the organic EL elements are used.

2. Description of the Related Art

The organic EL elements have features such as self-luminousness and rapid response and are predicted to be widely utilized for flat panel displays. Particularly, since two-layered or multilayered organic EL elements were announced that comprise an organic thin film having hole transport properties, or hole-transporting layer, and an organic thin film having electron transport properties, or electron-transporting layer (see, for example, “C. W. Tang and S. A. VanSlyke, Applied Physics Letters vol. 51, pp. 913, 1987”), the organic EL elements have been attracting attention as large area light-emitting elements which can emit light at as low voltage as 10 V or less. Such multilayered organic EL elements comprise a basic configuration of positive electrode/hole-transporting layer/light-emitting layer/electron-transporting layer/negative electrode, in which the hole-transporting layer or the electron-transporting layer may also perform as the light-emitting layer in the two-layered organic EL element.

Recently, organic EL elements are expected for full-color displays. In the full-color display, pixels showing three primary colors, i.e., blue (B), green (G), and red (R), are necessary to be arranged on a panel. For arranging the pixels, various methods are proposed such as (a) methods of arranging three different organic EL elements emitting blue (B), green (G), and red (R) light, respectively; (b) methods of separating white light (color mixture of blue (B), green (G), and red (R) light) emitted from a white-light-emitting organic EL element into the three primary colors using a color filter; and (c) methods of converting blue light from a blue-light-emitting organic EL element into green (G) light and red (R) light with the use of a color conversion layer utilizing fluorescence emission. In all of these methods, blue (B) light emission is indispensable, so it is desirable to provide an organic EL element for emitting blue light with high luminance, high luminous efficiency and high color purity.

As the organic EL element for emitting blue light, for example, in order to obtain an organic EL element emitting blue light with high heat resistance and satisfactory color purity, an organic EL element is proposed that comprises a diamine compound having a substituent group of N-phenylcarbazole as a host material in a light-emitting layer (see, Japanese Patent Application Laid-Open (IP-A) No. 2000-21572). In this case, however, luminous efficiency was less than sufficient. Further, JP-A No. 07-90256 proposes an organic EL element in which the hole-transporting layer is comprised of a triphenylbenzene derivative, which can improve the heat resistance of the hole-transporting layer, can reduce the influences of the heat, generated upon application of a current, on the hole-transporting layer, and can achieve high luminance. In this case, improvement of heat resistance enhances lifetime; however, it is not clear whether or not blue light emission with high color purity can be obtained.

Separately, in order to obtain organic EL elements with higher luminous efficiency, an organic EL element is proposed that comprises a light-emitting layer exhibiting high emission efficiency which is produced from a host material, as the main component, doped with a small amount of dye having a higher fluorescence luminescence as a guest material (see, “C. W. Tang, S. A. VanSlyke, and C. H. Chen, Journal of Applied Physics vol. 65, pp. 3610, 1989”). For example, an organic EL element is disclosed in which 4,4′-bis(9-carbazolyl)-biphenyl (CBP) is used as the host material and a 1,3,6,8-tetraphenylpyrene compound is used as the guest material in the light-emitting layer (see, JP-A No. 2003-234190). This organic EL element achieved improved emission luminance, luminous efficiency, and color purity, but, was not sufficient as an organic EL element for providing high-performance organic EL displays in terms of luminous efficiency. Further, it is known that iridium-containing organometallic compound is used as the guest material and 1,3,5-tris(carbazole-9-yl)-benzene is used as the host material (see, JP-A No. 2003-253256). In this case, however, the resulting organic EL element is an organic EL element for emitting red light, and therefore could not meet the demand for organic EL elements for emitting blue light having high color purity.

Therefore, there has been a demand for further improvements in material, etc. enhancing emission luminance, luminous efficiency, and color purity, especially, with respect to emission efficiency. When organic EL elements are used in display devices as a display element, the range of current density, applied to the organic EL element, is different depending on the driving method of the display device. Thus, the organic EL element is required to exhibit high luminous efficiency over a wide range of current densities covering driving currents. Namely, in the active-matrix type drive employing TFT, the current density applied to an element is a range of 1 mA/cm² to 40 mA/cm², and in the passive-matrix type drive, a simple matrix, a range of 100 mA/cm² to 500 mA/cm². However, organic EL elements have not been provided yet that have high luminance and high color purity, and besides, can achieve sufficient luminous efficiency over a wide range of current densities.

An object of the present invention is to solve conventional problems mentioned above and to achieve the following objects. Specifically, an object of the present invention is to provide an organic EL element which has high luminous efficiency over a wide range of current densities covering driving currents, high luminance, and satisfactory color purity, and a high-performance organic EL display in which the organic EL element is used.

### SUMMARY OF THE INVENTION

The present inventors have investigated vigorously in order to solve the problems described above, and have found the following experiences or discoveries. Specifically, when a specific 1,3,6,8-tetraphenylpyrene compound is used as a guest material, the use of a specific triphenylbenzene derivative as a host material enables an organic EL element having high luminous efficiency over a wide range of current densities covering driving currents, high luminance, and satisfactory color purity. Such organic EL element can be suitably used in both organic EL displays, passive-matrix panels and active-matrix panels.

The organic EL element of the invention is characterized in that the organic thin layer comprises a specific 1,3,6,8-tetraphenylpyrene compound and specific triphenylbenzene derivative. Thus, organic EL element of the invention has high luminous efficiency, high luminance, and satisfactory color purity.

Specifically, in these organic EL elements, the organic thin layer thereof comprises a specific 1,3,6,8-tetraphenylpyrene compound as a guest material, and further comprises a specific triphenylbenzene derivative as a host material capable of emitting light with a wavelength near to the absorption wavelength of the guest material. As a host material, the main component, the triphenylbenzene derivative that has high crystallization temperature and provides proper film-forming property is used, thus the organic thin layer may be formed successfully. In the light-emitting layer of the organic thin layer, the holes injected from the positive electrode recombine with the electrons injected from the negative electrode, and thereby molecules of recombination site are excited. Since the light-emitting layer comprises the guest material (1,3,6,8-tetraphenylpyrene compound) and the host material (triphenylbenzene derivative), both compounds can provide the recombination site. In the light-emitting layer, the host material, as the main component, provides more recombination site. When the host material provides the recombination site, the host material is initially excited. When the emission wavelength of the host material (triphenylbenzene derivative) overlaps the absorption wavelength of the guest material (1,3,6,8-tetraphenylpyrene compound), excitation energy is efficiently transferred from the host material to the guest material, and since the host material returns to the ground state without emitting light and only the guest material which is in an excited state emits excitation energy as blue light, the emission efficiency, emission luminance, and color purity of blue light are excellent.

Moreover, the organic EL element of the invention has high luminous efficiency over a wide range of current densities covering driving currents and thus can be suitably used in both organic EL displays, passive-matrix panels and active-matrix panels. In one aspect, the 1,3,6,8-tetraphenylpyrene compound is preferably a 1,3,6,8-tetra(4-biphenyl)pyrene compound. In another aspect, the triphenylbenzene derivative is preferably 1,3,5-tris[4-(N-carbazolyl)phenyl]benzene (TCPB).

The organic EL display of the invention is formed from the organic EL element of the invention. Therefore, the organic EL display has high luminous efficiency, high luminance, satisfactory color purity, and represents high performance.

### BRIEF DESCRIPTION OF THE DRAWING

FIG. 1 is a schematic view that illustrates an exemplary layer configuration of an organic EL element of the invention.

FIG. 2 is a schematic view that illustrates an exemplary configuration of an organic EL display of passive-matrix type or passive-matrix panel.

FIG. 3 is a schematic view that illustrates a circuit of an organic EL display of passive-matrix type or passive-matrix panel shown in FIG. 2.

FIG. 4 is a schematic view that illustrates an exemplary configuration of an organic EL display of active-matrix type or active-matrix panel.

FIG. 5 is a schematic view that illustrates a circuit of an organic EL display of active-matrix type or active-matrix panel shown in FIG. 4.

FIG. 6 is a schematic view that illustrates an aspect of an organic EL display wherein a hole-injecting layer and a hole-transporting layer are shared between the organic EL elements of each color.

FIG. 7A is a graph showing a relationship between a current density and luminous efficiency of organic EL elements of Examples 1 and 2 and Comparative Examples 1 and 2.

FIG. 7B is a graph showing a relationship between a current density and external quantum efficiency of organic EL elements of Examples 1 and 2 and Comparative Examples 1 and 2.

FIG. 8A is a graph showing a relationship between a current density and luminous efficiency of organic EL elements of Examples 3 to 7 and Comparative Example 3.

FIG. 8B is a graph showing a relationship between a current density and external quantum efficiency of organic EL elements of Examples 3 to 7 and Comparative Example 3.

### DESCRIPTION OF THE PREFERRED EMBODIMENTS

(Organic EL Element)

The organic EL element of the invention comprises an organic thin layer which comprises at least a light-emitting layer, between a positive electrode and a negative electrode, wherein a layer in the organic thin layer comprises a 1,3,6,8-tetraphenylpyrene compound (1,3,6,8-tetraphenylpyrene and its derivatives) expressed by the following structural formula (1) and a triphenylbenzene derivative expressed by the following structural formula (2):

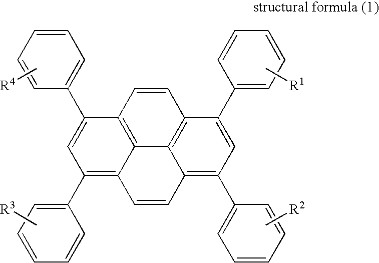

where R¹ to R⁴ may be identical or different each other, and represent a hydrogen atom, or at least one of an alkyl group, cycloalkyl group, and aryl group, which may have a substituent group;

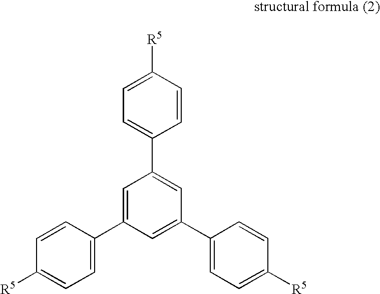

where, in the structural formula (2), R⁵ represents a carbazole skeleton expressed by the following structural formula (3):

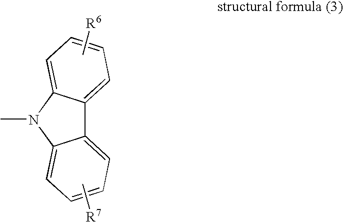

where, in the structural formula (3), R⁶ and R⁷ may be identical or different each other, and represent a hydrogen atom, or a substituent group.

Among the 1,3,6,8-tetraphenylpyrene compounds expressed by the structural formula (1), compounds of which R¹ to R⁴ are a phenyl group which may have a substituent group, i.e., 1,3,6,8-tetra(4-biphenyl)pyrene compounds expressed by the following structural formula (4) are preferable for excellent emission efficiency, emission luminance, etc. of blue light:

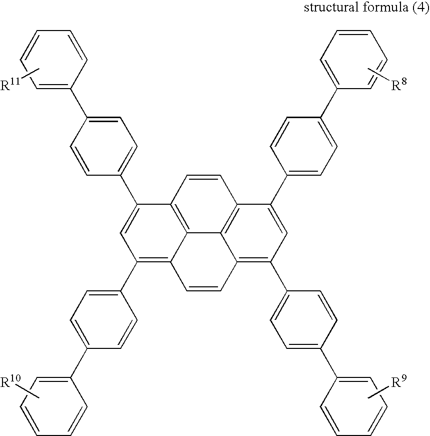

where R⁸ to R¹¹ may be identical or different each other, and represent a hydrogen atom, or at least one of an alkyl group, cycloalkyl group, and aryl group, which may have a substituent group.

In the organic EL element of the invention, among the triphenylbenzene derivatives expressed by the structural formula (2), such a triphenylbenzene derivative that R⁶ and R⁷ in the structural formula (3) are hydrogen, i.e., 1,3,5-tris[4-(N-carbazolyl)phenyl]benzene (TCPB) expressed by the following structural formula (5) is preferable for excellent emission efficiency, emission luminance, and color purity of blue light.

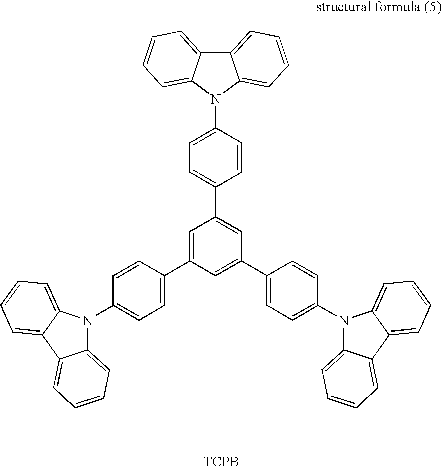

The 1,3,6,8-tetraphenylpyrene compound and triphenylbenzene derivative are contained in the organic thin layer, preferably contained in at least one of an electron-transporting layer, hole-transporting layer and light-emitting layer in the organic thin layer, and more preferably contained in the light-emitting layer.

In the organic thin layer (the light-emitting layer), the 1,3,6,8-tetraphenylpyrene compound functions as a guest material, and the triphenylbenzene derivative functions as a host material. Namely, the absorption wavelength of the 1,3,6,8-tetraphenylpyrene compound is 330 nm to 400 nm, and among the triphenylbenzene derivatives, the 1,3,5-tris[4-(N-carbazolyl)phenyl]benzene (TCPB) has an main emission wavelength of 360 nm. The 1,3,5-tris[4-(N-carbazolyl)phenyl]benzene (TCPB) has its absorption wavelength in a shorter region than that of the 1,3,6,8-tetraphenylpyrene compound and has its emission wavelength near to the absorption wavelength of the 1,3,6,8-tetraphenylpyrene compound, the emission wavelength and the absorption wavelength overlapping. Thus, excitation energy is efficiently transferred from the excited host material, (1,3,5-tris[4-(N-carbazolyl)phenyl]benzene (TCPB)), to the guest material, (1,3,6,8-tetraphenylpyrene compound), and the host material returns to the ground state without emitting light and only the guest material, (1,3,6,8-tetraphenylpyrene compound), which is in an excited state emits excitation energy as blue light. This configuration may therefore provide excellent emission efficiency, emission luminance, and color purity of blue light.

In addition, the use of 1,3,5-tris[4-(N-carbazolyl)phenyl]benzene (TCPB) as the host material is advantageous, since the TCPB provides proper film-forming property, thus it is able to form the organic thin layer or the light-emitting layer successfully regardless of the film-forming property of the 1,3,6,8-tetraphenylpyrene compound itself.

The organic thin layer may comprise two or more types of host material unless it affects the effect of the invention.

The content of the 1,3,6,8-tetraphenylpyrene compound in the layer comprising the 1,3,6,8-tetraphenylpyrene compound expressed by the structural formula (1) (the organic thin layer) is preferably 1% by mass to 20% by mass, and more preferably 5% by mass to 15% by mass.

The content of the 1,3,6,8-tetra(4-biphenyl)pyrene compound in the layer comprising the 1,3,6,8-tetra(4-biphenyl)pyrene compound expressed by the structural formula (4) (the organic thin layer) is preferably 5% by mass to 12% by mass, and more preferably 6% by mass to 10% by mass.

When the content is less than the lower limit of the preferable range, the emission efficiency, emission luminance, color purity etc. may be insufficient; and when the content is more than the upper limit, the color purity may be lower. In contrast, when the content is within the preferable range, emission efficiency, emission luminance, and color purity, etc. are satisfactory, and when the content is within the more preferable range, emission efficiency, emission luminance, and color purity, etc. are excellent.

The organic thin layer is not particularly limited as long as it comprises at least the light-emitting layer, and may be properly selected depending on the application. For example, the organic thin layer may comprise a hole-injecting layer, hole-transporting layer, hole-blocking layer, electron-transporting layer, electron-injecting layer, and the like.

The layer configuration of the organic EL element of the invention is not particularly limited and may be properly selected depending on the application; suitable examples thereof include the following layer configurations (1) to (13):

(1) Positive electrode/hole-injecting layer/hole-transporting layer/light-emitting layer/electron-transporting layer/electron-injecting layer/negative electrode,

(2) Positive electrode/hole-injecting layer/hole-transporting layer/light-emitting layer/electron-transporting layer/negative electrode,

(3) Positive electrode/hole-transporting layer/light-emitting layer/electron-transporting layer/electron-injecting layer/negative electrode,

(4) Positive electrode/hole-transporting layer/light-emitting layer/electron-transporting layer/negative electrode,

(5) Positive electrode/hole-injecting layer/hole-transporting layer/light-emitting and electron-transporting layer/electron-injecting layer/negative electrode

(6) Positive electrode/hole-injecting layer/hole-transporting layer/light-emitting and electron-transporting layer/negative electrode,

(7) Positive electrode/hole-transporting layer/light-emitting and electron-transporting layer/electron-injecting layer/negative electrode,

(8) Positive electrode/hole-transporting layer/light-emitting and electron-transporting layer/negative electrode,

(9) Positive electrode/hole-injecting layer/hole-transport and light-emitting layer/electron-transporting layer/electron-injecting layer/negative electrode

(10) Positive electrode/hole-injecting layer/hole-transport and light-emitting layer/electron-transporting layer/negative electrode,

(11) Positive electrode/hole-transport and light-emitting layer/electron-transporting layer/electron-injecting layer/negative electrode,

(12) Positive electrode/hole-transporting and light-emitting layer/electron-transporting layer/negative electrode,

(13) Positive electrode/hole-transport, light-emitting and electron-transporting layer/negative electrode. When the organic EL element comprises the hole-blocking layer, the hole-blocking layer is preferably arranged between the light-emitting layer and the electron-transporting layer in the layer configurations (1) to (13).

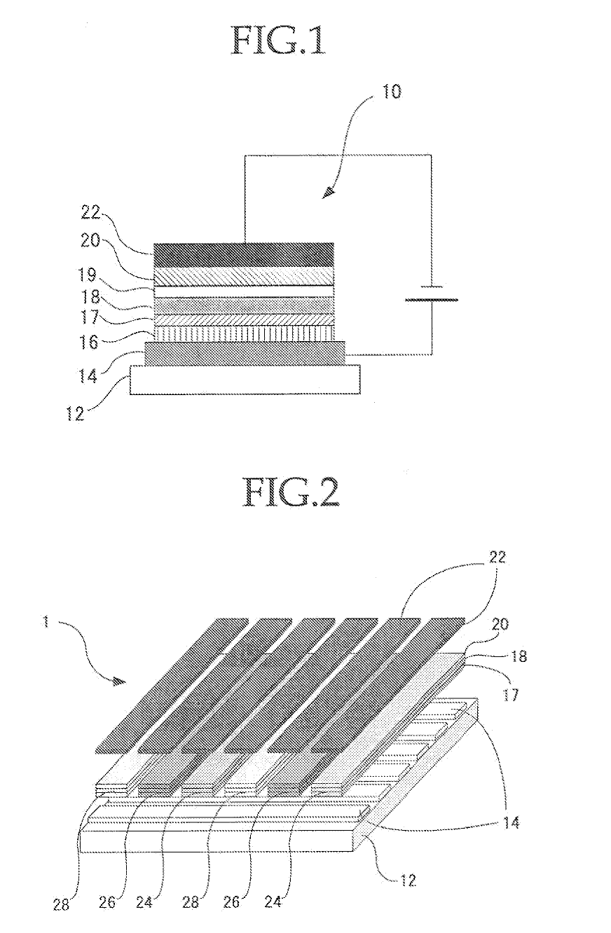

Among these layer configurations, an aspect of the layer configuration in which the layer configuration (4) further comprises the hole-blocking layer, i.e., positive electrode/hole-injecting layer/hole-transporting layer/light-emitting layer/hole-blocking layer/electron-transporting layer/negative electrode, is illustrated in FIG. 1. Organic EL element 10 has a layer configuration comprising positive electrode 14 (e.g. ITO electrode) formed on glass substrate 12, hole-injecting layer 16, hole-transporting layer 17, light-emitting layer 18, hole-blocking layer 19, electron-transporting layer 20, and negative electrode 22 (e.g. Al—Li electrode) laminated in this order. Positive electrode 14 (e.g. ITO electrode) and negative electrode 22 (e.g. Al—Li electrode) are interconnected through a power supply. The organic thin layer is formed by hole-injecting layer 16, hole-transporting layer 17, light-emitting layer 18, hole-blocking layer 19, and electron-transporting layer 20.

—Positive Electrode—

The positive electrode is not particularly limited and may be properly selected depending on the application. The positive electrode is preferably capable of supplying holes or carriers to the hole-injecting layer.

The material of the positive electrode is not particularly limited and may be properly selected depending on the application from metals, alloys, metal oxides, electrically conducting compounds, mixtures thereof and the like, for example. Among these, materials having a work function of 4 eV or more are preferable.

Specific examples of the material of the positive electrode include electrically conducting metal oxides such as tin oxide, zinc oxide, indium oxide, and indium tin oxide (ITO), metals such as gold, silver, chromium, and nickel, mixtures or laminates of these metals and electrically conducting metal oxides, inorganic electrically conducting substances such as copper iodide and copper sulfide, organic electrically conducting materials such as polyaniline, polythiophene and polypyrrole, and laminates of these with ITO. These may be used singly or in combination. Among these, electrically conducting metal oxides are preferable, and ITO is particularly preferable from the viewpoints of productivity, high conductivity, and transparency.

The thickness of the positive electrode is not particularly limited and may be properly selected depending on the material etc.; preferably the thickness is 1 nm to 5,000 nm, more preferably is 20 nm to 200 nm.

The positive electrode is typically formed on a substrate of glass such as soda lime glass and non-alkali glass, or transparent resin.

When the glass is employed as the substrate, non-alkali glass or soda lime glass with a barrier layer of silica or the like is preferable from the viewpoint suppressing the elution of ions from the glass.

The thickness of the substrate is not particularly limited provided that the mechanical strength is sufficient. When a glass is employed as the substrate, the thickness is typically 0.2 mm or more, preferably is 0.7 mm or more.

The positive electrode may be suitably formed by the above-mentioned methods such as a vapor deposition method, wet film forming method, electron beam method, sputtering method, reactive sputtering method, molecular beam epitaxy (MBE) method, cluster ion beam method, ion plating method, plasma polymerization method (high frequency excitation ion plating method), molecule laminating method, LB method, printing method, transfer method, and method of applying a dispersion of the ITO by chemical reaction method (sol-gel process etc.).

By washing the positive electrode and performing other treatment, the driving voltage of the organic EL element may be reduced, and the emission efficiency may also be increased. Suitable examples of other treatment include UV ozonization, plasma processing and the like, when the material of the positive electrode is ITO.

—Hole-Injecting Layer—

The hole-injecting layer is capable of injecting holes from the positive electrode when an electric field is applied, and capable of transporting the holes to the hole-transporting layer.

The material for the hole-injecting layer is not particularly limited and may be properly selected depending on the application. Suitable examples of the material include the starburst amine (4,4′,4″-tris[3-methylphenyl(phenyl)amino]triphenylamine: m-MTDATA) expressed by the following structural formula (6), copper phthalocyanine, and polyanilines.

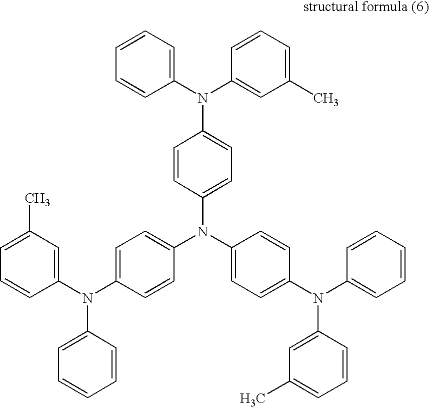

The hole-injecting layer can be suitably formed by the above-mentioned methods such as a vapor deposition method, wet film forming method, electron beam method, sputtering method, reactive sputtering method, molecular beam epitaxy (MBE) method, cluster ion beam method, ion plating method, plasma polymerization method (high frequency excitation ion plating method), molecule laminating method, LB method, printing method, and transfer method.

The vapor deposition method is not particularly limited and may be properly selected from known methods depending on the application. Examples thereof include a vacuum vapor deposition, resistance heating vapor deposition, chemical vapor deposition, physical vapor deposition, and the like. Examples of chemical vapor deposition include plasma CVD, laser CVD, heat CVD, gas source CVD, and the like.

The wet film forming method is not particularly limited and may be properly selected from known methods depending on the application. Examples thereof include an ink-jet method, spin coating method, kneader coating method, bar coating method, blade coating method, casting method, dipping method, curtain coating method, and the like.

In the wet film forming method, a solution may be used or applied into which the material of the hole-injecting layer is dissolved or dispersed together with a resin component. Examples of the resin component include polyvinyl carbazoles, polycarbonates, polyvinyl chlorides, polystyrenes, polymethyl methacrylates, polyesters, polysulfones, polyphenylene oxides, polybutadiene, hydrocarbon resins, ketone resins, phenoxy resins, polyamides, ethyl cellulose, vinyl acetate, acrylonitrile ABS resins, polyurethane, melamine resins, unsaturated polyester resins, alkyd resins, epoxy resins, and silicone resins.

The hole-injecting layer may be suitably prepared by the wet film forming method, for example, by means of a solution of coating composition that contains a material for the hole-injecting layer and the optional resin material dissolved in a solvent, for example, by applying and drying the coating composition.

The solvent may be properly selected without particular limitations from conventional solvents, and commercial products can be suitably used as the solvent. Examples thereof include FC77 (by 3M), Vertrel XF (by DuPont Co.) and the like.

The thickness of the hole-injecting layer is not particularly limited, may be properly selected depending on the application, and is, for example, preferably 10 nm to 1,000 nm, more preferably 40 nm to 300 nm.

When the thickness of the hole-injecting layer is less than 40 nm, short circuit of the positive electrodes and negative electrodes is more likely to occur, and when it is less than 10 nm, short circuit of the positive electrodes and negative electrodes may occur. On the other hand, when the thickness of the hole-injecting layer is more than 300 nm, holes may be difficult to flow into the light-emitting layer smoothly, and when it is more than 1,000 nm, holes may not flow smoothly.

—Hole-Transporting Layer—

The hole-transporting layer is not particularly limited and may be properly selected depending on the application; preferably, the hole-transporting layer is capable of transporting holes from the hole-injecting layer when an electric field is applied.

The material of the hole-transporting layer is not particularly limited and may be properly selected depending on the application; examples thereof include aromatic amine compounds, carbazole, imidazole, triazole, oxazole, oxadiazole, polyarylalkane, pyrazoline, pyrazolone, phenylene diamine, arylamine, amino-substituted chalcone, styryl anthracene, fluorenone, hydrazone, stilbene, silazane, styryl amine, aromatic dimethylidene compounds, porphyrin compounds, electrically conducting high-molecular oligomers and polymers such as polysilane compounds, poly(N-vinyl carbazole), aniline copolymers, thiophene oligomers and polymers, and polythiophene, and carbon films. When one of these materials for hole-transporting layer is mixed with a material for the light-emitting layer to form a film, a hole-transporting and light-emitting layer can be formed.

These materials of the hole-transporting layer may be used singly or in combination. Among these, aromatic amine compounds are preferable, and specifically, TPD (N,N′-diphenyl-N,N′-bis(3-methylphenyl)-[1,1′-biphenyl]4,4′-diamine) expressed by the following structural formula (7), and NPD (N,N′-dinaphthyl-N,N′-diphenyl-[1,1′-biphenyl]4,4′-diamine) expressed by the following structural formula (8), and the like are more preferable.

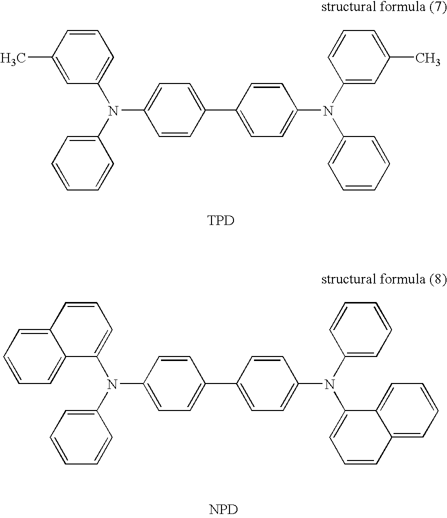

The thickness of the hole-transporting layer is not particularly limited and may be properly selected depending on the application; usually the thickness is 1 nm to 500 nm, and preferably is 10 nm to 100 nm.

The hole-transporting layer may be suitably formed by the above-mentioned methods such as a vapor deposition method, wet film forming method, electron beam method, sputtering method, reactive sputtering method, molecular beam epitaxy (MBE) method, cluster ion beam method, ion plating method, plasma polymerization method (high frequency excitation ion plating method), molecule laminating method, LB method, printing method, and transfer method.

—Light-Emitting Layer—

The light-emitting layer may inject holes from the positive electrode, hole injecting layer, hole-transporting layer, or the like when an electric field is applied, and also may inject electrons from the negative electrode, electron-injecting layer, electron-transporting layer, or the like; thus, the light-emitting layer may provide a field of recombination between the holes and the electrons and may enable the 1,3,6,8-tetraphenylpyrene compound or the 1,3,6,8-tetra(4-biphenyl)pyrene compound emitting blue light, to emit light by the action of recombination energy generated by the recombination. The light-emitting layer may further comprise other light-emitting materials in addition to these compounds within a range not deteriorating the blue light emission.

The light-emitting layer may be suitably produced by conventional methods such as a vapor deposition method, wet film forming method, MBE (molecular beam epitaxial) method, cluster ion beam method, molecule laminating method, LB method, printing method, transfer method, and the like.

The thickness of the light emitting layer is preferably 1 nm to 50 nm, and more preferably is 3 nm to 40 nm.

The light-emitting layer having a thickness within the preferable range may lead to sufficient emission efficiency, emission luminance, and color purity emitted by the organic EL element. The light-emitting layer having a thickness within the more preferable range is advantageous in that those are more remarkable.

The light-emitting layer may be designed to perform also as the hole-transporting layer and/or the electron-transporting layer, such as a light-emitting and electron-transporting layer, or a light-emitting and hole-transporting layer.

—Hole-Blocking Layer—

The hole-blocking layer is not particularly limited and may be properly selected depending on the application; such a layer is preferable that may perform to barrier the holes injected from the positive electrode.

When the organic EL element comprises the hole-blocking layer, holes transported from the positive electrode are blocked by the hole-blocking layer, and electrons transported from the negative electrode are transmitted through this hole-blocking layer to reach the light-emitting layer. Hence, recombination of electrons and holes occurs efficiently in the light-emitting layer, and recombination of the holes and electrons in the organic thin layer other than the light-emitting layer can be prevented. Thus, the luminescence from a light-emitting material, which is intended, is obtained efficiently, and this is advantageous in respect of color purity.

The hole-blocking layer can be disposed at any position in the EL element without limitation and may be properly selected depending on the application. It is preferable that when the organic thin layer comprises the 1,3,6,8-tetraphenylpyrene compound expressed by the structural formula (1), the hole-blocking layer is disposed between the layer comprising the 1,3,6,8-tetraphenylpyrene compound expressed by the structural formula (1) and the negative electrode because this configuration may provide excellent emission efficiency, color purity, etc. When the 1,3,6,8-tetraphenylpyrene compound expressed by the structural formula (1) is a 1,3,6,8-tetra(4-biphenyl)pyrene compound, the hole-blocking layer is preferably disposed between the layer comprising the 1,3,6,8-tetra(4-biphenyl)pyrene compound expressed by the structural formula (4) and the negative electrode, more preferably is disposed between the light-emitting layer and the electron-transporting layer because these configurations may provide excellent emission efficiency, color purity, etc.

The material for the hole-blocking layer is not particularly limited and may be properly selected depending on the application. When the hole-blocking layer is disposed between the layer comprising the 1,3,6,8-tetraphenylpyrene compound and the negative electrode, the hole-blocking layer preferably comprises 2,9-dimethyl-4,7-diphenyl-1,10-phenanthroline expressed by the following structural formula (9) (bathocuproine; BCP). This is advantageous for excellent emission efficiency, color purity, etc.

When the hole-blocking layer is disposed between the layer comprising the 1,3,6,8-tetra(4-biphenyl)pyrene compound and the negative electrode, the hole-blocking layer preferably comprises Bis-(2-methyl-8-quinolinolato)-4-(phenyl-phenolato)-aluminium (III) (BAlq) expressed by the following structural formula (10), which is advantageous in that emission efficiency, color purity, etc. are excellent and luminance deterioration can be prevented.

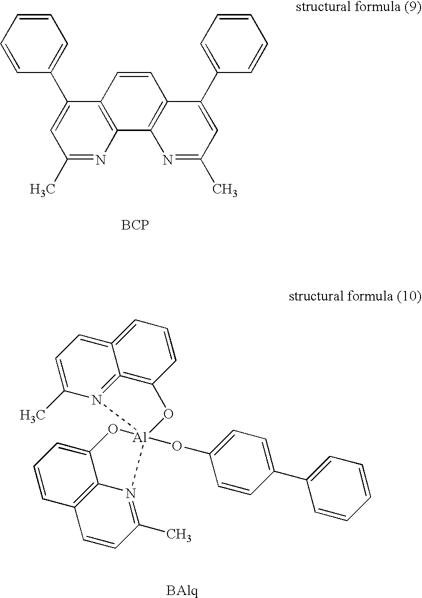

The thickness of the hole-blocking layer is not particularly limited and may be properly selected depending on the application; for example, usually the thickness is about 1 nm to about 500 nm, and preferably is 5 nm to 50 nm.

The hole-blocking layer may be of single layer or multilayered configuration.

The hole-blocking layer may be suitably formed by the above-mentioned methods such as a vapor deposition method, wet film forming method, electron beam method, sputtering method, reactive sputtering method, molecular beam epitaxy (MBE) method, cluster ion beam method, ion plating method, plasma polymerization method (high frequency excitation ion plating method), molecule laminating method, LB method, printing method, or transfer method.

—Electron-Transporting Layer—

The electron-transporting layer is not particularly limited and may be properly selected depending on the application; for example, such a layer is preferable that performs to transport electrons from the negative electrode, or to act as a barrier to holes injected from the positive electrode.

The material of the electron-transporting layer is not particularly limited and may be properly selected depending on the application; examples thereof include quinoline derivatives including organometallic complexes having as ligand 8-quinolinol or its derivatives, such as tris(8-quinolinolato)aluminum (Alq) expressed by the following structural formula (11), oxadiazole derivatives, triazole derivatives, phenanthroline derivatives, perylene derivatives, pyridine derivatives, pyrimidine derivatives, quinoxaline derivatives, diphenylquinone derivatives and nitro-substituted fluorene derivatives.

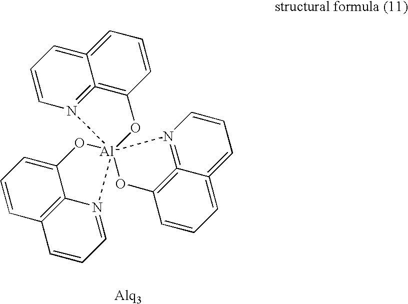

The thickness of the electron-transporting layer is not particularly limited and may be properly selected depending on the application; for example, usually the thickness is about 1 nm to about 500 nm, and preferably is 10 nm to 50 nm.

The electron-transporting layer may be of single layer or multilayered configuration.

The electron-transporting layer can be suitably formed by the above-mentioned methods such as a vapor deposition method, wet film forming method, electron beam method, sputtering method, reactive sputtering method, molecular beam epitaxy (MBE) method, cluster ion beam method, ion plating method, plasma polymerization method (high frequency excitation ion plating method), molecule laminating method, LB method, printing method, or transfer method.

—Electron-Injecting Layer—

The electron-injecting layer is not particularly limited and may be properly selected depending on the application; preferably, the electron-injecting layer is capable of injecting electrons from the negative electrode and capable of sending the electrons to the electron-transporting layer.

The material of the electron-injecting layer is not particularly limited and may be properly selected depending on the application. Examples thereof include alkaline metal fluoride such as lithium fluoride, alkaline earth metal fluoride such as strontium fluoride, and the like.

The thickness of the electron-injecting layer is not particularly limited and may be properly selected depending on the application; for example, the thickness is usually about 0.1 nm to about 10 nm, preferably is 0.2 nm to 2 nm.

The electron-injecting layer can be suitably formed by the above-mentioned methods such as a vapor deposition method, wet film forming method, electron beam method, sputtering method, reactive sputtering method, molecular beam epitaxy (MBE) method, cluster ion beam method, ion plating method, plasma polymerization method (high frequency excitation ion plating method), molecule laminating method, LB method, printing method, or transfer method.

—Negative Electrode—

The negative electrode is not particularly limited and may be properly selected depending on the application. It is preferable that the negative electrode supplies electrons to the organic thin layer, specifically, to a light-emitting layer when the organic thin layer comprises only the light-emitting layer or to the electron-transporting layer when the organic thin layer further comprises the electron-transporting layer, or to an electron-injecting layer when the electron-injecting layer is present between the organic thin layer and the negative electrode.

The material of the negative electrode is not particularly limited and may be properly selected depending on the adhesion properties with the layers or molecules adjoining the negative electrode, such as the electron-transporting layer and light-emitting layer, and according to ionization potential, stability and the like. Examples thereof include a metal, alloy, metal oxide, electrically conducting compound, and mixture thereof.

Specific examples of the material of the negative electrode include alkali metals such as Li, Na, K, and Cs; alkaline earth metals such as Mg and Ca; gold, silver, lead, aluminum, sodium-potassium alloys or mixed metals thereof, lithium-aluminum alloys or mixed metals thereof, magnesium-silver alloys or mixed metals thereof; rare earth metals such as indium and ytterbium; and alloys of these metals.

These may be used singly or in combination. Among these, materials having a work function of 4 eV or less are preferable. Aluminum, lithium-aluminum alloy or mixed metals thereof, magnesium-silver alloy, or mixed metals thereof, or the like are more preferable.

The thickness of the negative electrode is not particularly limited and may be properly selected depending on the material of the negative electrode and the like; preferably the thickness is 1 nm to 10,000 nm, more preferably is 20 nm to 200 nm.

The negative electrode can be suitably formed by the above-mentioned methods such as a vapor deposition method, wet film forming method, electron beam method, sputtering method, reactive sputtering method, molecular beam epitaxy (MBE) method, cluster ion beam method, ion plating method, plasma polymerization method (high frequency excitation ion plating method), molecule laminating method, LB method, printing method, and transfer method.

When two or more materials are used together as the material of the negative electrode, the materials may be vapor-deposited simultaneously to form an alloy electrode or the like, or a pre-prepared alloy may be vapor-deposited to form an alloy electrode or the like.

Preferably, the resistances of the positive electrode and negative electrode are lower, and are below several hundreds ohm/square.

—Other Layers—

The organic EL element of the invention may have other layers properly selected depending on the application. Suitable examples of the other layer include a protective layer, and the like.

The protective layer is not particularly limited and may be properly selected depending on the application; for example, such a layer is preferable that can prevent molecules or substances as moisture or oxygen which promote deterioration of the organic EL element, from penetrating into the organic EL element.

Examples of the material of the protective layer include metals such as In, Sn, Pb, Au, Cu, Ag, Al, Ti and Ni; metal oxides such as MgO, SiO, SiO₂, A₂O₃, GeO, NiO, CaO, BaO, Fe₂O₃, Y₂O₃ and TiO₂; nitrides such as SiN and SiNxOy; metal fluorides such as MgF₂, LiF, AiF₃, CaF₂; polyethylene, polypropylene, polymethyl methacrylate, polyimide, polyurea, polytetrafluoroethylene, polychlorotrifluoroethylene, polydichlorodifluoroethylenek, copolymer of chlorotrifluoroethylene and dichlorodifluoroethylene, copolymer obtained by copolymerizing a monomer mixture comprising tetrafluoroethylene and at least one comonomer, fluorine-containing copolymer having a ring structure in a main chain of the copolymer, water-absorbing substance having a water absorption rate of 1% or more, and damp proof substance having a water absorption rate of 0.1% or less.

The protective layer may be suitably formed by, for example, the above-mentioned methods such as a vapor deposition method, wet film forming method, sputtering method, reactive sputtering method, molecular beam epitaxy (MBE) method, cluster ion beam method, ion plating method, plasma polymerization method (high frequency excitation ion plating method), printing method, and transfer method.

With respect to emission efficiency, desirably, the organic EL element of the invention is capable of emitting blue light at voltages of 10 V or less, preferably at voltages of 7 V or less, and more preferably at voltages of 5 V or less.

In a condition that the current density applied to an element is within a range of 1 mA/cm² to 500 mA/cm², the luminous efficiency is preferably 1.5 cd/A or more, and more preferably 4.0 cd/A or more. Organic EL displays can, for example, be formed into passive-matrix panels, or active-matrix panels. In case of the passive-matrix panel, the current density applied to an element is from 100 mA/cm² to 500 mA/cm², and in case of the active-matrix panel, from 1 mA/cm² to 40 mA/cm². Therefore, if luminous efficiency is constantly high within a current density of 1 mA/cm² to 500 mA/cm², such organic EL element can be suitably used in both passive-matrix panels and active-matrix panels.

The emission luminance of the organic EL element of the invention is preferably 100 cd/m² or more, more preferably is 500 cd/m² or more, and still more preferably is 1,000 cd/m² or more at applying a voltage of 10 V.

The organic EL elements of the invention may be appropriately utilized in a variety of regions such as computers, on-vehicle displays, outdoor displays, household appliances, commercial equipment, household equipment, traffic displays, clock displays, calendar displays, luminescent screens, and audio equipment; in addition, may be preferably utilized for the following organic EL displays of the invention.

(Organic EL Display)

The organic EL display of the invention is not particularly limited, and the construction may be conventional, provided that the organic EL element of the invention is included.

The organic EL display may be a monochrome, multicolor, or full color type.

With respect to methods for providing the full-color organic EL display, the representative methods are, as illustrated in “Monthly Display, September 2000 issue, pages 33 to 37”, three-color light emitting methods in which organic EL elements each emitting light corresponding to the three primary colors, red (R), green (G), or blue (B) light, are disposed on a substrate; white color methods in which white light from a white light emitting organic EL element is separated into three primary colors through a color filter; and color conversion methods in which blue light from a blue light emitting organic EL element is converted into red (R) and green (G) colors through a fluorescent dye layer.

Providing a full-color organic EL display by the three-color light emitting method requires an organic EL element for emitting red light and an organic EL element for emitting green light, in addition to the organic EL element of the invention for emitting blue light.

The organic EL element for emitting red light is not particularly limited and may be properly selected from those known in the art. Suitable examples thereof include such an organic EL element that has a layer configuration of ITO (positive electrode)/NPD aforesaid/DCJTB expressed by the following formula, 1% aluminum quinoline complex (Alq)/Alq aforesaid/Al—Li (negative electrode), and the like. The above-mentioned DCJTB is 4-dicyanomethylene-6-cp-julolidinostyryl-2-tert-butyl-4H-pyran expressed by the following structural formula (12). The Alq is as described above.

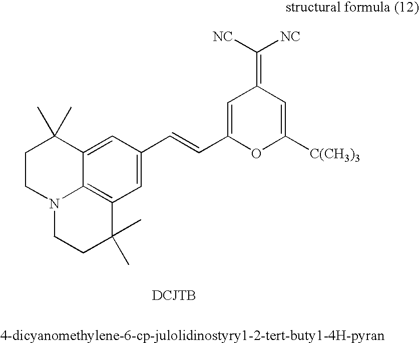

The organic EL element for emitting green light is not particularly limited and may be properly selected from those known in the art. Suitable examples thereof include such an organic EL element that has a layer configuration of ITO (positive electrode)/NPD aforesaid/dimethyl quinacdorin 1% Alq aforesaid/Alq aforesaid/Al—Li (negative electrode), and the like.

The configuration of the organic EL display is not particularly limited, may be properly selected depending on the application and may be, for example, a passive-matrix panel or an active-matrix panel as illustrated in “Nikkei Electronics, No. 765, Mar. 13, 2000, pages 55 to 62”.

The passive-matrix panel comprises, for example, glass substrate 12, band-like positive electrodes 14 of e.g. ITO electrodes, organic thin layer 24 for emitting blue light, organic thin layer 26 for emitting green light, organic thin layer 28 for emitting red light, and negative electrodes 22 as shown in FIG. 2. The positive electrodes 14 are arranged in parallel with each other on the glass substrate 12. The organic thin layer 24 for emitting blue light, the organic thin layer 26 for emitting green light, and the organic thin layer 28 for emitting red light are arranged in parallel with one another in turn on the positive electrodes 14 in a direction substantially perpendicular to the positive electrodes 14. The negative electrodes 22 are arranged on the organic thin layer 24 for emitting blue light, the organic thin layer 26 for emitting green light, and the organic thin layer 28 for emitting red light in a direction perpendicular to the positive electrodes 14.

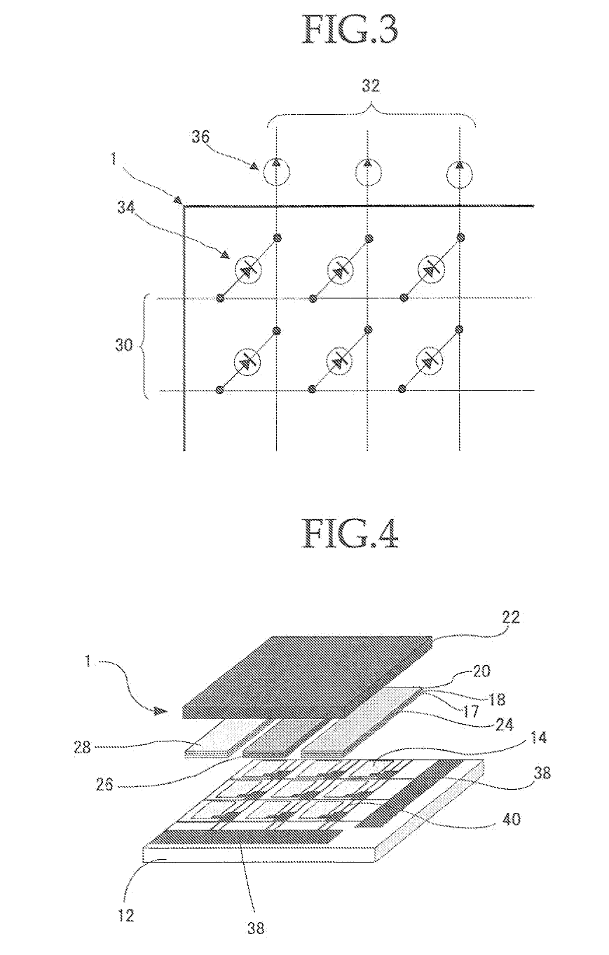

In the passive-matrix panel, for example as shown in FIG. 3, positive electrode lines 30 each having plural positive electrodes 14 intersect negative electrode lines 32 each having plural negative electrodes 22 in a substantially perpendicular direction to form a circuit. The organic thin layers 24, 26, and 28 for emitting, blue, green, and red lights, respectively, are arranged at intersections and serve as pixels. Plural organic EL elements 34 are arranged corresponding to the respective pixels. Upon application of a current by constant-current power supply 36 on one of the positive electrodes 14 in the positive electrode lines 30 and one of the negative electrodes 22 in the negative electrode lines 32 in the passive-matrix panel, the current is applied on an organic EL thin layer at the intersection between the lines to allow the organic EL thin layer at the position to emit light. By controlling light emission of each pixel independently, full-color images can be easily produced.

With reference to FIG. 4, the active-matrix panel comprises, for example, glass substrate 12, scanning lines, data lines and current supply lines, TFT circuits 40, and positive electrodes 14. The scanning lines, data lines, and current supply lines are arranged on glass substrate 12 as grids in a rectangular arrangement. The TFT circuits 40 are connected typically to the scanning lines constituting the grids and are arranged in each grid. The positive electrodes 14 may be, for example, ITO electrodes, are capable of being driven by the TFT circuits 40 and are arranged in each grid. Organic thin layer 24 for emitting blue light, organic thin layer 26 for emitting green light, and organic thin layer 28 for emitting red light each has a narrow shape and is arranged in parallel with each other in turn on the positive electrodes 14. Negative electrode 22 is arranged so as to cover these layers. The organic thin layer 24 for emitting blue light, the organic thin layer 26 for emitting green light, and the organic thin layer 28 for emitting red light each comprise hole-injecting layer 16 (not shown), hole-transporting layer 17, light-emitting layer 18, and electron-transporting layer 20.

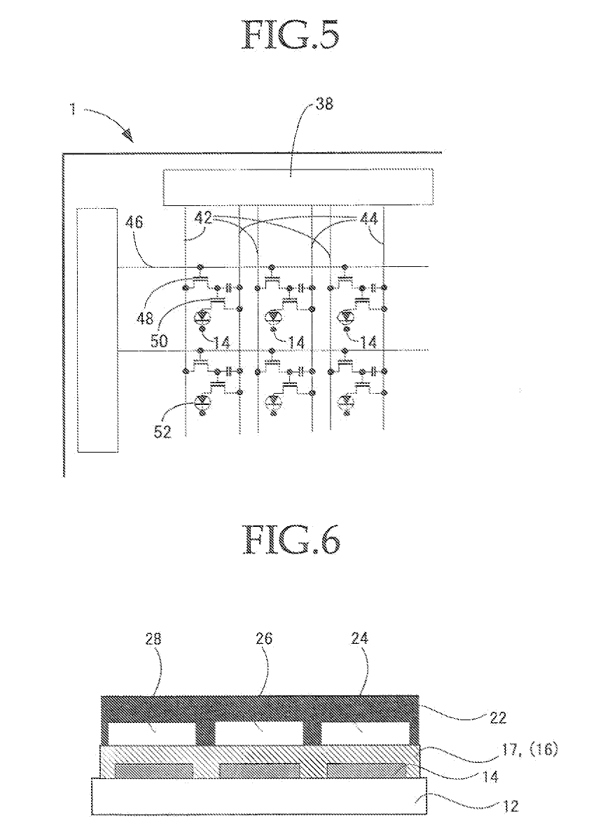

In the active-matrix panel, for example as shown in FIG. 5, scanning lines 46 intersect with data lines 42 and current-supply lines 44 in a perpendicular direction to form grids in a rectangular arrangement. The scanning lines 46 are arranged in parallel with one another. The data lines 42 and current-supply lines 44 are arranged in parallel with one another. Switching TFT 48 and drive TFT 50 are arranged in each grid to form a circuit. The switching TFT 48 and the drive TFT 50 in each grid can be independently derived by the application of a current by drive circuit 38. In each grid, the organic thin film elements 24, 26 and 28 for emitting blue, green, and red lights, respectively serve as pixels. Upon application of a current from the drive circuit 38 to one of the scanning lines 46 arranged in a lateral direction and to the current-supply lines 44 arranged in a vertical direction, switching TFT 48 positioned at the intersection operates to drive the drive TFT 50 to allow organic EL element 52 at the position to emit light. By controlling light emission of each pixel independently, a full-color image can be easily produced.

In the invention, a structure is also preferable in which at least one of the hole-transporting layer 17 and the hole-injecting layer 16 in FIGS. 2 and 4 is not patterned, and is shared by the organic thin layer 24 for emitting blue light, organic thin layer 26 for emitting green light, and organic thin layer 28 for emitting red light, as shown in FIG. 6. This structure is advantageous in that patterning of the hole-transporting layer 17 is unnecessary and the structure is simple, making the production easy, and in addition, short circuit of the positive electrodes and negative electrodes can be prevented.

The organic EL display of the invention can be suitably used in a variety of regions such as computers, on-vehicle displays, outdoor displays, household appliances, commercial equipment, household equipment, traffic displays, clock displays, calendar displays, luminescent screens, and audio equipment.

The invention will be illustrated with reference to several examples below, which are not intended to limit the scope of the invention.

### EXAMPLE 1

—Preparation of Organic EL Element—

A multilayered organic EL element, in which 1,3,6,8-tetraphenylpyrene and 1,3,5-tris[4-(carbazolyl)phenyl]benzene (TCPB) were used in a light-emitting layer, was prepared in the following manner.

A glass substrate having an ITO electrode as a positive electrode was subjected to ultrasonic cleaning with water, acetone, and isopropyl alcohol and to UV ozone treatment; thereafter a layer of 2-TNATA expressed by the following structural formula (13) as a hole-injecting layer of 140 nm thick was formed by vapor deposition on the ITO electrode using a vacuum vapor deposition apparatus at a vacuum of 1×10⁻⁶ Torr (1.3×10⁻⁴ Pa) and at ambient temperature.

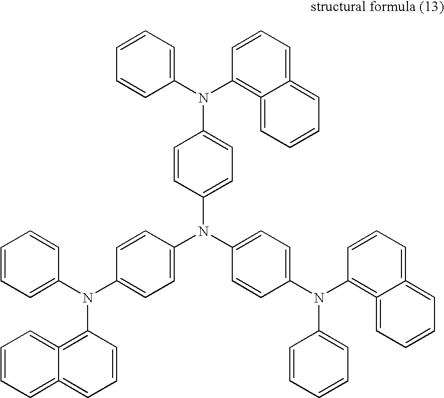

Next, a layer of α-NPD expressed by the following structural formula (14) as a hole-transporting layer of 10 mm thick was formed by vapor deposition on the hole-injecting layer.

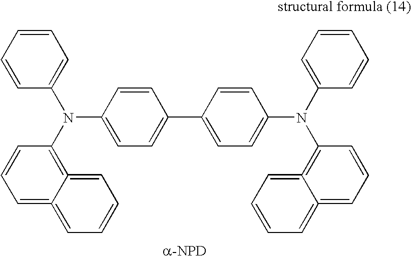

Then, onto the hole-transporting layer a film of 90% by mass of 1,3,5-tris[4-(carbazolyl)phenyl]benzene (TCPB) expressed by the following structural formula (5) doped with 10% by mass of 1,3,6,8-tetraphenylpyrene was vapor deposited thereby to form a light-emitting layer of 20 nm thick.

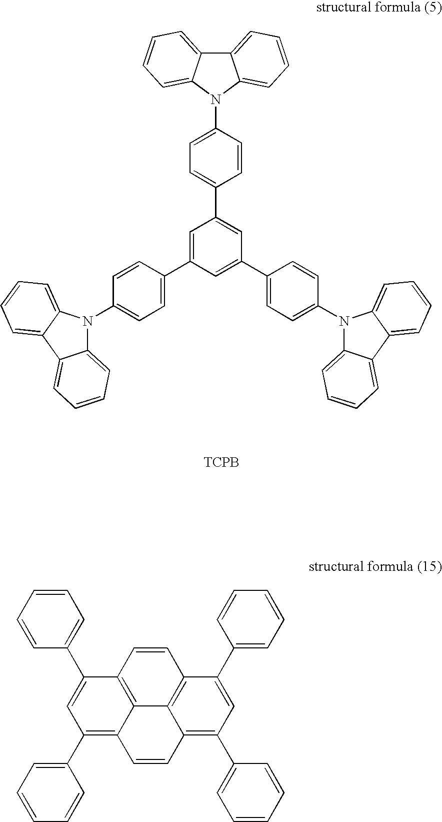

A layer of 2,9-dimethyl-4,7-diphenyl-1,10-phenanthroline (bathocuproine; BCP) expressed by the following structural formula (9) as a hole-blocking layer of 10 nm thick was formed by vapor deposition on the light-emitting layer.

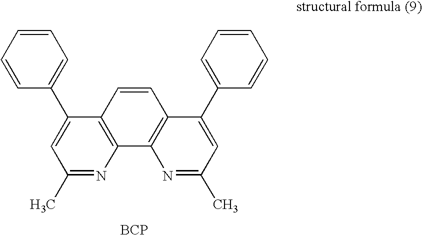

Then, a layer of tris(8-quinolinolato)aluminum (Alq) as an electron-transporting layer of 20 nm thick was formed by vapor deposition on the hole-blocking layer, and a layer of LiF as an electron-injecting layer of 0.5 nm thick was formed by vapor deposition on the electron-transporting layer. Then, a layer of Al as a negative electrode of 100 nm thick was formed by vapor deposition on the electron-injecting layer. As a result, a multilayered organic EL element was prepared as shown in FIG. 1.

When a current was applied to the resulting organic EL element where the ITO electrode serves as the positive electrode and the Al serves as the negative electrode, emission of blue light was observed, and emission of highly pure blue light having an emission luminance of 238 cd/m² (CIE color coordinates of EL emission: x=0.157, y=0.107) was observed at a driving current of 15 mA/cm². The luminous efficiency, external quantum efficiency, driving voltage were 1.6 cd/A, 1.7%, and 9.16 V, respectively. At an emission luminance of 100 cd/m², luminous power efficiency was 0.65 lm/W.

### COMPARATIVE EXAMPLE 1

The organic EL element of Comparative Example 1 was prepared in the same way as Example 1, except for changing 1,3,5-tris[4-(carbazolyl)phenyl]benzene (TCPB) into 4,4′-bis(9-carbazolyl)-biphenyl (CBP) expressed by the following structural formula (16).

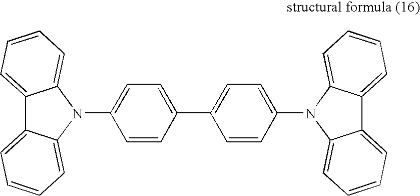

When a current was applied to the resulting organic EL element where the ITO electrode serves as the positive electrode and the Al serves as the negative electrode, emission of blue light was observed, and emission of blue light having an emission luminance of 174 cd/m² (CIE color coordinates of EL emission: x=0.158, y=0.105) was observed at a driving current of 15 mA/cm². The luminous efficiency, external quantum efficiency, driving voltage were 1.2 cd/A, 1.3%, and 8.79 V, respectively. At an emission luminance of 100 cd/m², luminous power efficiency was 0.47 lm/W.

### EXAMPLE 2

The organic EL element of Example 2 was prepared in the same way as Example 1, except that the thickness of light-emitting layer was changed from 20 nm to 30 nm, and hole-blocking layer was not formed. When a current was applied to the resulting organic EL element where the ITO electrode serves as the positive electrode and the Al serves as the negative electrode, emission of blue light was observed, and emission of highly pure blue light having an emission luminance of 243 cd/m² (CIE color coordinates of EL emission: x=0.159, y=0.120) was observed at a driving current of 15 mA/cm². The luminous efficiency, external quantum efficiency, driving voltage were 1.6 cd/A, 1.6%, and 8.89 V, respectively. At an emission luminance of 100 cd/m², luminous power efficiency was 0.69 lm/W.

### COMPARATIVE EXAMPLE 2

The organic EL element of Comparative Example 2 was prepared in the same way as Example 2, except for changing 1,3,5-tris[4-(carbazolyl)phenyl]benzene (TCPB) into 4,4′-bis(9-carbazolyl)-biphenyl (CBP). When a current was applied to the resulting organic EL element where the ITO electrode serves as the positive electrode and the Al serves as the negative electrode, emission of blue light was observed, and emission of blue light having an emission luminance of 192 cd/m² (CIE color coordinates of EL emission: x=0.168, y=0.150) was observed at a driving current of 15 mA/cm². The luminous efficiency, external quantum efficiency, driving voltage were 1.3 cd/A, 1.1%, and 8.27 V, respectively. At an emission luminance of 100 cd/m², luminous power efficiency was 0.56 lm/W.

### EXAMPLE 3

—Preparation of Organic EL Element—

A multilayered organic EL element, in which 1,3,6,8-tetra(4-biphenyl)pyrene and 1,3,5-tris[4-(N-carbazolyl)phenyl]benzene (TCPB) were used in a light-emitting layer, was prepared in the following manner.

A glass substrate having an ITO electrode as a positive electrode was subjected to ultrasonic cleaning with water, acetone, and isopropyl alcohol and to UV ozone treatment; thereafter a layer of 2-TNATA as a hole-injecting layer of 140 nm thick was formed by vapor deposition on the ITO electrode using a vacuum vapor deposition apparatus at a vacuum of 1×10⁻⁶ Torr (1.3×10⁴ Pa) and at ambient temperature. Next, a layer of α-NPD as a hole-transporting layer of 10 nm thick was formed by vapor deposition on the hole-injecting layer. Then, onto the hole-transporting layer a film of 90% by mass of 1,3,5-tris[4-(N-carbazolyl)phenyl]benzene (TCPB) expressed by the structural formula (5) doped with 10% by mass of 1,3,6,8-tetra(4-biphenyl)pyrene expressed by the following structural formula (17) was vapor deposited thereby to form a light-emitting layer of 20 nm thick.

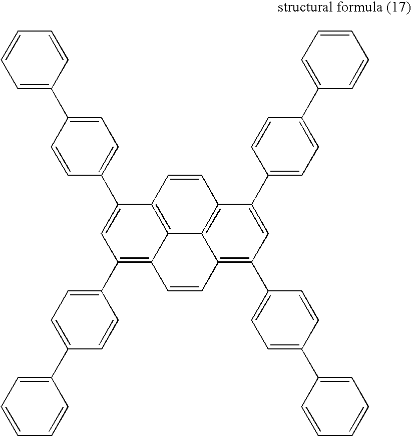

A layer of BAlq expressed by the following structural formula (10) as a hole-blocking layer of 10 nm thick was formed by vapor deposition on the light-emitting layer.

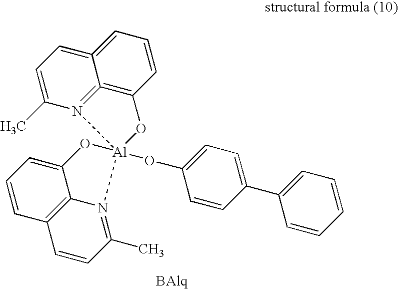

A layer of Alq as an electron-transporting layer of 20 nm thick was formed by vapor deposition on the hole-blocking layer, and a layer of LiF as an electron-injecting layer of 0.5 nm thick was formed by vapor deposition on the electron-transporting layer. Then, a layer of Al as a negative electrode of 100 nm thick was formed by vapor deposition on the electron-injecting layer. As a result, a multilayered organic EL element was prepared as shown in FIG. 1.

When a current was applied to the resulting organic EL element where the ITO electrode serves as the positive electrode and the Al serves as the negative electrode, emission of blue light was observed, and emission of highly pure blue light having an emission luminance of 649 cd/m² (CIE color coordinates of EL emission: x=0.155, y=0.191) was observed at a driving current of 15 mA/cm². The luminous efficiency, external quantum efficiency, driving voltage were 4.4 cd/A, 2.9%, and 8.84 V, respectively. At an emission luminance of 100 cd/m², luminous power efficiency was 2.5 lm/W.

### COMPARATIVE EXAMPLE 3

The organic EL element of Comparative Example 3 was prepared in the same way as Example 3, except for changing 1,3,5-tris[4-(carbazolyl)phenyl]benzene (TCPB) into 4,4′-bis(9-carbazolyl)-biphenyl (CBP). When a current was applied to the resulting organic EL element where the ITO electrode serves as the positive electrode and the Al serves as the negative electrode, emission of blue light was observed, and emission of blue light having an emission luminance of 452 cd/m² (CIE color coordinates of EL emission: x=0.162, y=0.201) was observed at a driving current of 15 mA/cm². The luminous efficiency, external quantum efficiency, driving voltage were 3.0 cd/A, 1.9%, and 8.19 V, respectively. At an emission luminance of 100 cd/m², luminous power efficiency was 1.8 lm/W.

### EXAMPLE 4

The organic EL element of Example 4 was prepared in the same way as Example 3, except that a layer of 99.9% by mass of 2-TNATA doped with 0.1% by mass of F4-TCNQ (2,3,5,6-tetrafluoro-7,7,8,8 tetracyanoquinodimethane) as a hole-injecting layer of 210 nm thick was formed by vapor deposition, and the doping amount of 1,3,6,8-tetra(4-biphenyl)pyrene in the light-emitting layer was changed to 12% by mass. When a current was applied to the resulting organic EL element where the ITO electrode serves as the positive electrode and the Al serves as the negative electrode, emission of blue light was observed, and emission of highly pure blue light having an emission luminance of 709 cd/m² (CIE color coordinates of EL emission: x=0.145, y=0.169) was observed at a driving current of 15 mA/cm². The luminous efficiency, external quantum efficiency, driving voltage were 4.7 cd/A, 3.6%, and 7.86 V, respectively. At an emission luminance of 100 cd/m², luminous power efficiency was 2.8 lm/W.

### EXAMPLE 5

The organic EL element of Example 5 was prepared in the same way as Example 3, except that a layer of 99.9% by mass of 2-TNATA doped with 0.1% by mass of F4-TCNQ as a hole-injecting layer of 210 nm thick was formed by vapor deposition, and the doping amount of 1,3,6,8-tetra(4-biphenyl)pyrene in the light-emitting layer was changed to 10% by mass. When a current was applied to the resulting organic EL element where the ITO electrode serves as the positive electrode and the Al serves as the negative electrode, emission of blue light was observed, and emission of highly pure blue light having an emission luminance of 669 cd/m² (CIE color coordinates of EL emission: x=0.145, y=0.163) was observed at a driving current of 15 mA/cm². The luminous efficiency, external quantum efficiency, driving voltage were 4.5 cd/A, 3.5%, and 7.92 V, respectively. At an emission luminance of 100 cd/m², luminous power efficiency was 2.7 lm/W.

### EXAMPLE 6

The organic EL element of Example 6 was prepared in the same way as Example 3, except that a layer of 99.9% by mass of 2-TNATA doped with 0.1% by mass of F4-TCNQ as a hole-injecting layer of 210 nm thick was formed by vapor deposition, and the doping amount of 1,3,6,8-tetra(4-biphenyl)pyrene in the light-emitting layer was changed to 8% by mass. When a current was applied to the resulting organic EL element where the ITO electrode serves as the positive electrode and the Al serves as the negative electrode, emission of blue light was observed, and emission of highly pure blue light having an emission luminance of 594 cd/m² (CIE color coordinates of EL emission: x=0.145, y=0.153) was observed at a driving current of 15 mA/cm². The luminous efficiency, external quantum efficiency, driving voltage were 4.0 cd/A, 3.2%, and 8.00 V, respectively. At an emission luminance of 100 cd/m², luminous power efficiency was 2.4 lm/W.

### EXAMPLE 7

The organic EL element of Example 7 was prepared in the same way as Example 3, except that a layer of 99.9% by mass of 2-TNATA doped with 0.1% by mass of F4-TCNQ as a hole-injecting layer of 210 nm thick was formed by vapor deposition, and the doping amount of 1,3,6,8-tetra(4-biphenyl)pyrene in the light-emitting layer was changed to 5% by mass. When a current was applied to the resulting organic EL element where the ITO electrode serves as the positive electrode and the Al serves as the negative electrode, emission of blue light was observed, and emission of highly pure blue light having an emission luminance of 473 cd/m² (CIE color coordinates of EL emission: x=0.145, y=0.141) was observed at a driving current of 15 mA/cm². The luminous efficiency, external quantum efficiency, driving voltage were 3.2 cd/A, 2.7%, and 8.17 V, respectively. At an emission luminance of 100 cd/m², luminous power efficiency was 1.8 lm/W.

The emission luminance at a driving current of 15 mA/cm², CIE color coordinates (x, y) of EL emission, luminous efficiency, external quantum efficiency, driving voltage, and luminous power efficiency at an emission luminance of 100 cd/m², of thus obtained organic EL elements of Examples 1 to 7 and Comparative Examples 1 to 3 are shown in Tables 1 and 2. Tables 1 and 2 show, respectively, the results of organic EL elements of Examples 1 and 2 and Comparative Examples 1 and 2 where the light-emitting layer was formed using 1,3,6,8-tetraphenylpyrene as a guest material; and the results of organic EL elements of Examples 3 to 7 and Comparative Example 3 where the light-emitting layer was formed using 1,3,6,8-tetra(4-biphenyl)pyrene as a guest material.

TABLE 1

| | | | | | | | Current Density |
|---|---|---|---|---|---|---|---|
| | Driving Current (Current Density) 15 mA/cm² | | | | | | 100 mA/cm² |
| | Emission | | | Luminous | External Quantum | Driving | Luminous Power |
| | Luminance | Color Purity | | Efficiency | Efficiency | Voltage | Efficiency |
| | (cd/m2) | x | y | (cd/A) | (%) | (V) | (lm/W) |
| Example 1 | 238 | 0.157 | 0.107 | 1.6 | 1.7 | 9.16 | 0.65 |
| Example 2 | 243 | 0.159 | 0.120 | 1.6 | 1.6 | 8.89 | 0.69 |
| Comparative | 174 | 0.158 | 0.105 | 1.2 | 1.3 | 8.79 | 0.47 |
| Example 1 | | | | | | | |
| Comparative | 192 | 0.168 | 0.150 | 1.3 | 1.1 | 8.72 | 0.56 |
| Example 2 | | | | | | | |

From the results of Table 1, it was found that when 1,3,6,8-tetraphenylpyrene was used as a guest material, the organic EL elements of Examples 1 and 2 comprising a light-emitting layer, in which 1,3,5-tris[4-N-(carbazolyl)phenyl]benzene (TCPB) was used as a host material, have higher luminance and higher efficiency compared with the respective organic EL elements of Comparative Examples 1 and 2 at the same current density. Although the organic EL element of Example 2 does not comprise a hole-blocking layer, it exhibits high luminance and high efficiency as the organic EL element of Example 1 comprising the hole-blocking layer, indicating that the organic EL element of the invention enables the reduction of the number of layers in the organic thin layer, and thus the simplification of laminated layer and reduction of production cost can be achieved.

TABLE 2

| | | | | | | | Current Density |
|---|---|---|---|---|---|---|---|
| | Driving Current (Current Density) 15 mA/cm² | | | | | | 100 mA/cm² |
| | Emission | | | Luminous | External Quantum | Driving | Luminous Power |
| | Luminance | Color Purity | | Efficiency | Efficiency | Voltage | Efficiency |
| | (cd/m2) | x | y | (cd/A) | (%) | (V) | (lm/W) |
| Example 3 | 649 | 0.155 | 0.191 | 4.4 | 2.9 | 8.84 | 2.5 |
| Example 4 | 709 | 0.155 | 0.169 | 4.7 | 3.6 | 7.86 | 2.8 |
| Example 5 | 669 | 0.145 | 0.163 | 4.5 | 3.5 | 7.92 | 2.7 |
| Example 6 | 594 | 0.145 | 0.153 | 4.0 | 3.2 | 8.00 | 2.4 |
| Example 7 | 473 | 0.145 | 0.141 | 3.2 | 2.7 | 8.17 | 1.8 |
| Comparative | 452 | 0.162 | 0.201 | 3.0 | 1.9 | 8.19 | 1.8 |
| Example 3 | | | | | | | |

From the results of Table 2, it was found that when 1,3,6,8-tetra(4-biphenyl)pyrene was used as a guest material, the organic EL elements of Examples 3 to 7 comprising a light-emitting layer, in which 1,3,5-tris[4-N-(carbazolyl)phenyl]benzene (TCPB) was used as a host material, had extremely high luminance and high efficiency. In case of blue light emission, the smaller the values of x and y are, the higher the color purity is, thus demonstrating that the organic EL elements of Examples 3 to 7 had improved color purity compared with the organic EL element of Comparative Example 3.

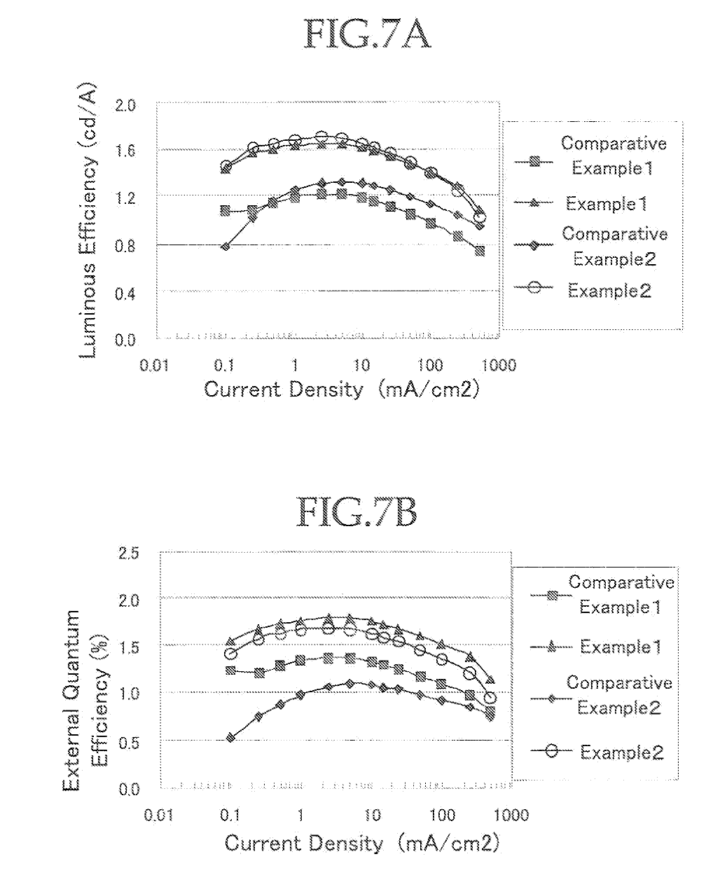

With respect to organic EL elements of Examples 1 and 2 and Comparative Examples 1 and 2 of which light-emitting layer was formed using 1,3,6,8-tetraphenylpyrene as a guest material, a relationship between a current density and luminous efficiency and a relationship between a current density and external quantum efficiency are shown in FIGS. 7A and 7B, respectively.

From FIGS. 7A and 7B, it was found that the organic EL elements of Examples 1 and 2 exhibited high luminous efficiency and high external quantum efficiency over a wide range of current densities (0.1 mA/cm² to 500 mA/cm²).

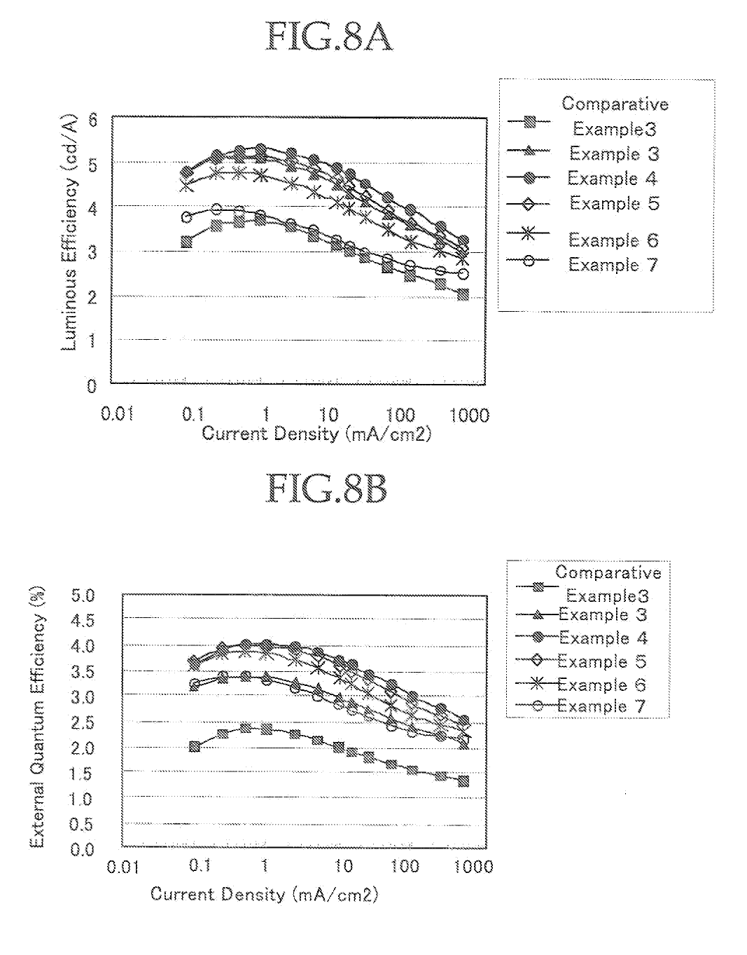

Further, with respect to organic EL elements of Examples 3 to 7 and Comparative Example 3 of which light-emitting layer was formed using 1,3,6,8-tetra(4-biphenyl)pyrene as a guest material, a relationship between a current density and luminous efficiency and a relationship between a current density and external quantum efficiency are shown in FIGS. 8A and 8B, respectively.

From FIGS. 8A and 8B, it was found that the organic EL elements of Examples 3 to 7 exhibited high luminous efficiency and high external quantum efficiency over a wide range of current densities (0.1 mA/cm² to 500 mA/cm²), and the values were extraordinary high. In addition, it was found that high value of the external quantum efficiency was obtained stably without depending on the doping amount of 1,3,6,8-tetra(4-biphenyl)pyrene.

As described above, the organic EL element of the invention has an excellent luminous efficiency and external quantum efficiency over a wide range of current densities covering driving currents. Thus, the organic EL element of the invention exhibits high luminous efficiency both in a current density region of 1 mA/cm² to 40 mA/cm², the region applied to an element in an active-matrix type drive, and in a current density region of 100 mA/cm² to 500 mA/cm², the region applied to an element in a passive-matrix type drive, demonstrating that the organic EL element of the invention can be suitably used in both types of organic EL display.

The organic EL element of the invention has high luminous efficiency over a wide range of current densities covering driving currents, high luminance, and satisfactory color purity, and thus can be suitably used in both organic EL displays, passive-matrix panels and active-matrix panels. The organic EL display of the invention uses the organic EL element of the invention, thus representing high performance. These can be suitably used in a variety of regions such as computers, on-vehicle displays, outdoor displays, household appliances, commercial equipment, household equipment, traffic displays, clock displays, calendar displays, luminescent screens, and audio equipment.

The invention can solve conventional problems and can provide an organic EL element which has high luminous efficiency over a wide range of current densities covering driving currents, high luminance, and satisfactory color purity; and a high-performance organic EL display in which the organic EL element is used.

What is claimed is:

1. An organic EL element comprising:
a positive electrode;
a negative electrode; and
an organic thin layer between the positive electrode and the negative electrode,
wherein the organic thin layer comprises a light-emitting layer,
wherein a layer in the organic thin layer comprises a 1,3,6,8-tetraphenylpyrene compound expressed by the following structural formula (1) and a triphenylbenzene derivative expressed by the following structural formula (2): 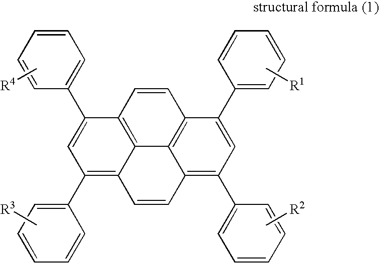
where, in the structural formula (1), R¹ to R⁴ may be identical or different each other, and represent a hydrogen atom, or at least one of an alkyl group, cycloalkyl group, and aryl group, which may have a substituent group; 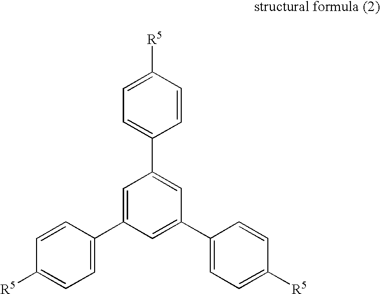
where, in the structural formula (2), R⁵ represents a carbazole skeleton expressed by the following structural formula (3): 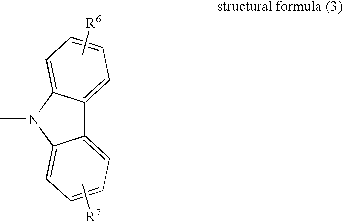
where, in the structural formula (3), R⁶ and R⁷ may be identical or different each other, and represent a hydrogen atom, or a substituent group.

2. The organic EL element according to claim 1, wherein the 1,3,6,8-tetraphenylpyrene compound expressed by the structural formula (1) is a 1,3,6,8-tetra(4-biphenyl)pyrene compound expressed by the following structural formula (4): 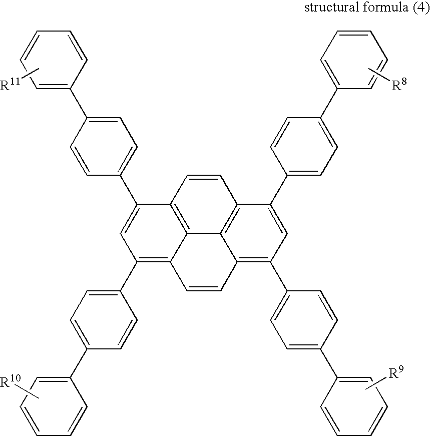
where, in the structural formula (4), R⁸ to R¹¹ may be identical or different each other, and represent a hydrogen atom, or at least one of an alkyl group, cycloalkyl group, and aryl group, which may have a substituent group.

3. The organic EL element according to claim 1, wherein the triphenylbenzene derivative expressed by the structural formula (2) is 1,3,5-tris[4-(N-carbazolyl)phenyl]benzene (TCPB) expressed by the following structural formula (5):

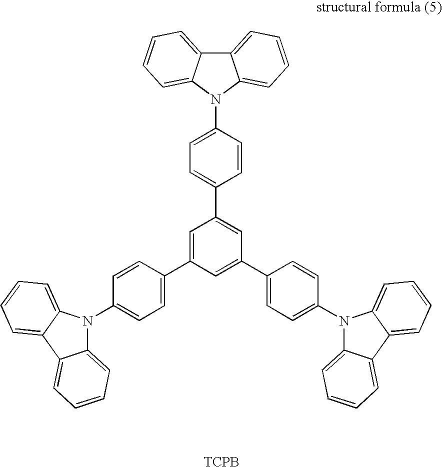

4. The organic EL element according to claim 1, wherein a content of the 1,3,6,8-tetraphenylpyrene compound in the layer which comprises the 1,3,6,8-tetraphenylpyrene compound expressed by the structural formula (1) is 1% by mass to 20% by mass.

5. The organic EL element according to claim 2, wherein a content of the 1,3,6,8-tetra(4-biphenyl)pyrene compound in the layer which comprises the 1,3,6,8-tetra(4-biphenyl)pyrene compound expressed by the structural formula (4) is 5% by mass to 12% by mass.

6. The organic EL element according to claim 5, wherein a content of the 1,3,6,8-tetra(4-biphenyl)pyrene compound in the layer which comprises the 1,3,6,8-tetra(4-biphenyl)pyrene compound expressed by the structural formula (4) is 6% by mass to 10% by mass.

7. The organic EL element according to claim 4, further comprising a hole-blocking layer between the layer which comprises the 1,3,6,8-tetraphenylpyrene compound expressed by the structural formula (1) and the negative electrode.

8. The organic EL element according to claim 7, wherein the hole-blocking layer comprises 2,9-dimethyl-4,7-diphenyl-1,10-phenanthroline (bathocuproine; BCP) expressed by the following structural formula (6):

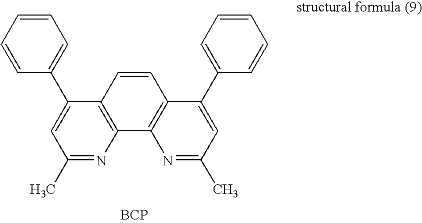

9. The organic EL element according to claim 5, further comprising a hole-blocking layer between the layer which comprises the 1,3,6,8-tetra(4-biphenyl)pyrene compound expressed by the structural formula (4) and the negative electrode.

10. The organic EL element according to claim 9, wherein the hole-blocking layer comprises BAlq expressed by the following structural formula (10):

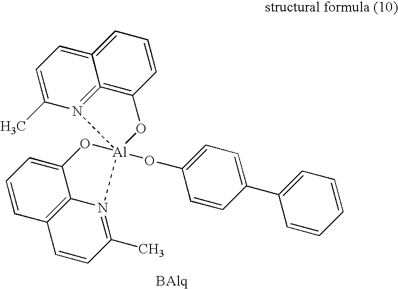

11. The organic EL element according to claim 1, wherein the light-emitting layer has a thickness of 5 nm to 50 nm.

12. The organic EL element according to claim 1, which is used for emitting blue light.

13. An organic EL display comprising an organic EL element,
wherein the organic EL element comprises:
a positive electrode;
a negative electrode; and
an organic thin layer between the positive electrode and the negative electrode,
wherein the organic thin layer comprises a light-emitting layer,
wherein a layer in the organic thin layer comprises a 1,3,6,8-tetraphenylpyrene compound expressed by the following structural formula (1) and a triphenylbenzene derivative expressed by the following structural formula (2): 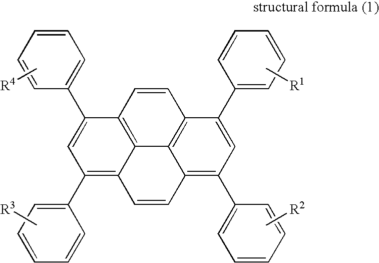
where, in the structural formula (1), R¹ to R⁴ may be identical or different each other, and represent a hydrogen atom, or at least one of an alkyl group, cycloalkyl group, and aryl group, which may have a substituent group; 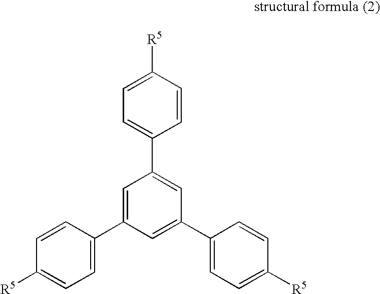
where, in the structural formula (2), R⁵ represents a carbazole skeleton expressed by the following structural formula (3): 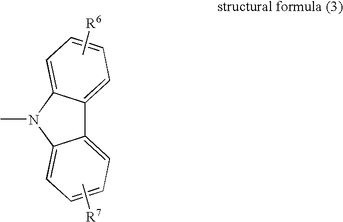
where, in the structural formula (3), R⁶ and R⁷ may be identical or different each other, and represent a hydrogen atom, or a substituent group.

14. The organic EL display according to claim 13, wherein the organic EL display is one of a passive-matrix panel and an active-matrix panel.

15. The organic EL display according to claim 13, comprising an organic EL element for emitting blue light, an organic EL element for emitting green light, and an organic EL element for emitting red light,
wherein the organic EL element for emitting blue light, the organic EL element for emitting green light, and the organic EL element for emitting red light each comprise at least one of a hole-injecting layer and a hole-transporting layer which are shared with other organic EL elements,
wherein the organic EL element for emitting blue light comprises:
a positive electrode;
a negative electrode; and
an organic thin layer between the positive electrode and the negative electrode,
wherein the organic thin layer comprises a light-emitting layer,
wherein a layer in the organic thin layer comprises a 1,3,6,8-tetraphenylpyrene compound expressed by the following structural formula (1) and a triphenylbenzene derivative expressed by the following structural formula (2): 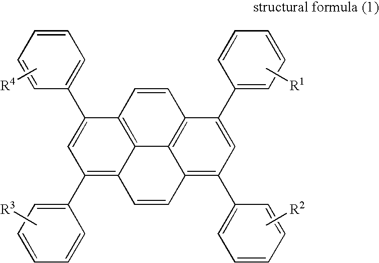
where, in the structural formula (1), R¹ to R⁴ may be identical or different each other, and represent a hydrogen atom, or at least one of an alkyl group, cycloalkyl group, and aryl group, which may have a substituent group; 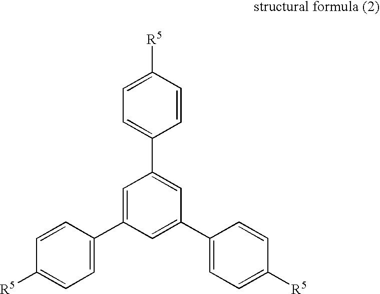
where, in the structural formula (2), R⁵ represents a carbazole skeleton expressed by the following structural formula (3): 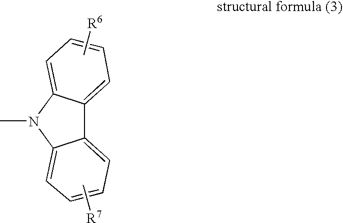
where, in the structural formula (3), R⁶ and R⁷ may be identical or different each other, and represent a hydrogen atom, or a substituent group.
